(19) United States
(12) Patent Application Publication
(10) Pub. No.: US 2003/0211738 A1
(43) Pub. Date: Nov. 13, 2003

(54) Method of detecting endpoint of etching

(76) Inventor: Tatsuya Nagata, Kanagawa (JP)

Correspondence Address: VOLENTINE FRANCOS, PLLC, Suite 150, 12200 Sunrise Vally Drive, Reston, VA, 20191, US

(21) Appl. No.: 10/235,495

(22) Filed: Sep. 6, 2002

(30) Foreign Application Priority Data
May 7, 2002 (JP) 131819/2002

(51) Int. Cl. H01L 21/00; H01L 21/302; H01L 21/461

(52) U.S. Cl. 438/689

(57) ABSTRACT

BF₂ for a channel stop is ion-implanted in a P-type silicon substrate, and a trench is defined in an area of the ion-implanted silicon substrate by etching. An intensity of light emission at a wavelength of 660 m when fluorine corresponding to a constituent element of BF₂ is alienated, is detected to thereby sense an endpoint of the etching, whereby a device isolation trench with a channel stop region formed therebelow is formed.

### BACKGROUND OF THE INVENTION

1. Field of the Invention:

The present invention relates to an etching endpoint detecting method, and particularly to a method of detecting an endpoint of etching for a trench used for device isolation or the like.

2. Description of the Related Art:

Device isolation has been used to electrically isolate between adjacent semiconductor elements or devices. With recent micro-fabrication of semiconductor devices, however, trench device isolation for defining trenches (grooves) in a silicon substrate has been used in place of the conventionally-used LOCOS isolation.

A conventional trench forming method is shown in FIG. 1. Resist patterns 102 are formed on a silicon substrate 101 (see FIG. 1A) (see FIG. 1B). The silicon substrate 101 is dry-etched with the resist patterns 102 as masks, so that a trench 103 can be defined (see FIG. 1D).

In this case, the amount of etching for the silicon substrate with respect to an etching time is measured in advance upon dry etching for trench formation. The etching time is determined based on the result of its measurement and the silicon substrate is etched to a predetermined depth.

In the above-described conventional trench forming method, however, etching control on the depth of the trench has been carried out in an etching time calculated based on pre-measured data. Therefore, the etching control depends on etching conditions such as the concentration of a plasma gas for dry etching, or the state of an etching system with high-frequency power or the like. Thus, an etching rate was difficult to keep constant, and the control on the depth of the trench was very difficult.

The present invention aims to solve the aforementioned problems and control the depth of etching at dry etching of a trench without depending on etching conditions such as the concentration of a plasma gas for the dry etching, or the state of an etching system using high-frequency power or the like.

### SUMMARY OF THE INVENTION

A trench dry etching method of the present invention comprises the steps of ion-implanting an impurity used as a specific compound in a semiconductor substrate, and detecting an intensity of light emitted from an element contained in the ion-implanted compound to detect an endpoint of etching, thereby defining a trench by etching.

Particularly, the present invention provides a method comprising the steps of ion-implanting BF₂ for a channel stop in a P-type silicon substrate, defining a trench in an area of the ion-implanted silicon substrate by etching, detecting an intensity of light emitted from a fluorine element of BF₂ to detect an endpoint of the etching, and defining a device isolation trench with a channel stop area formed therebelow.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIGS. 1A through 1D are respectively process diagrams showing a method of forming a trench by etching, which is employed in a prior art;

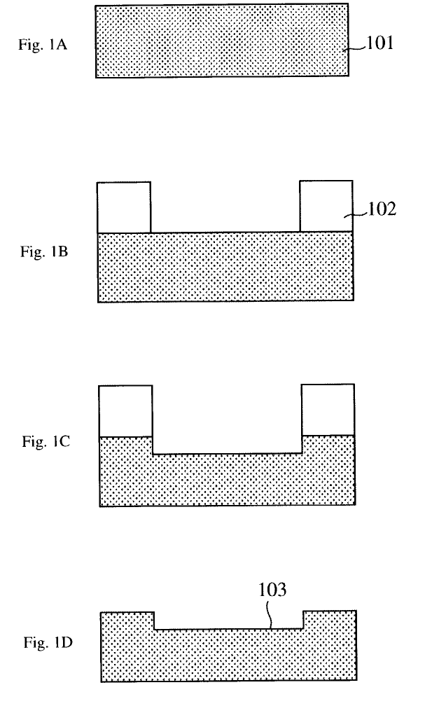

FIGS. 2A through 2D are respectively process diagrams illustrating a method of forming a trench by etching, for describing an embodiment of the present invention;

FIG. 3 is a diagram showing a change in the intensity of light emission where etching employed in the embodiment of the present invention has been carried out; and

FIG. 4 is a diagram illustrating an ion-implantation impurity distribution as viewed in a depth direction, which is obtained in the embodiment of the present invention.

### DETAILED DESCRIPTION OF THE INVENTION

A preferred embodiment of the present invention will hereinafter be described in detail with reference to the accompanying drawings.

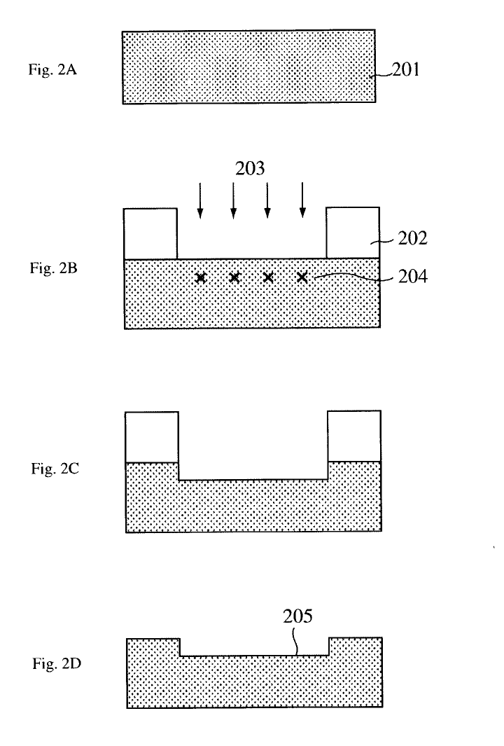

A process diagram at the time that a device isolating trench is defined in a P-type silicon substrate by etching in the present embodiment, is shown in FIG. 2. A P-type silicon substrate 201 (see FIG. 2A) containing a boron impurity or the like is first patterned by means of resists 202 (see FIG. 2B) . Then ion-implantation 203 of BF₂ is done under the condition of an acceleration of 70 KeV and a dose of 1.0E16 ps/cm² to thereby form an ion-implanting layer 204.

Subsequently, the silicon substrate is dry-etched by a mixture gas of HBr and O₂ to define a trench 205 inside the ion-implanting layer. At this time, the ion-implanting layer is placed in a state of remaining below the trench 205 and serves as a channel stop layer. Then the resist 202 is removed to make it possible to form the device isolating trench 205.

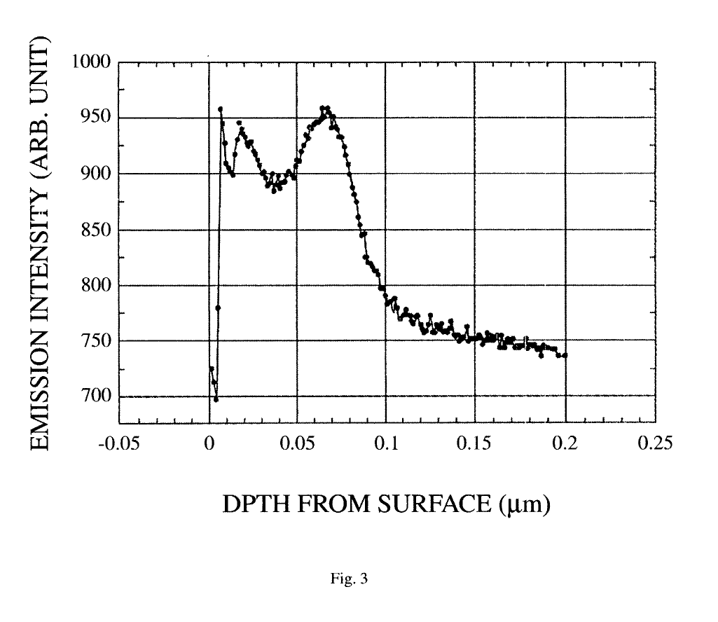

When the emission of plasma at a wavelength of 660 nm is observed upon the etching in the present embodiment, such a change in the intensity of light emission as shown in FIG. 3 is obtained. The light emission at the wavelength of 600 nm at this time is considered to be an emission spectrum at the alienation of fluorine (F).

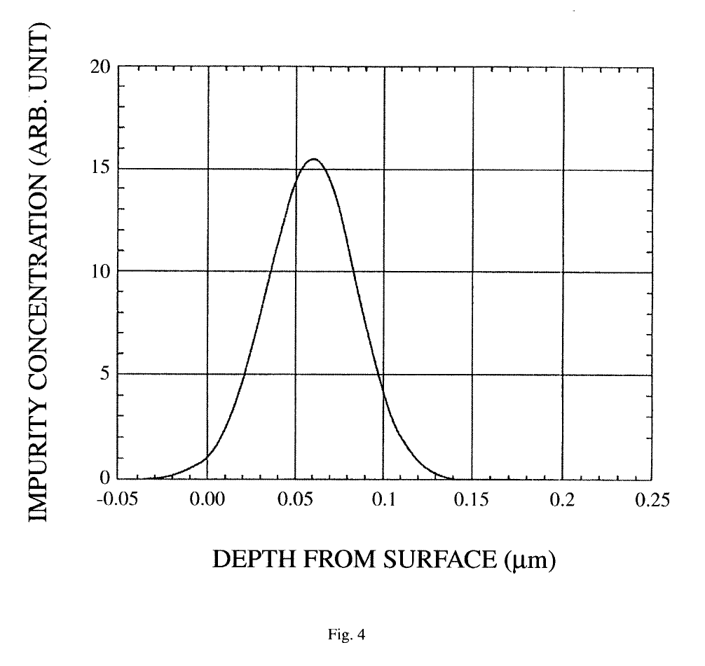

An impurity concentration profile at the ion implantation of BF₂ is illustrated in FIG. 4. The peak of an emission intensity at an etching depth of about 60 nm of the trench substantially coincides with the peak of an impurity profile. In the present embodiment, an endpoint detection can be carried out by detecting an emission intensity produced from fluorine.

Further, since the light emission of fluorine is not produced in the vicinity of 100 nm upon the dry etching described in the embodiment of the present invention, the endpoint of etching can be detected at a depth obtained by etching approximately all of a portion ion-implanted with BF₂. It is therefore possible to easily form a trench corresponding to an implanted depth at the ion implantation of BF₂.

As described above, the present invention can provide a method cable of accurately controlling the depth of etching at trench dry etching without depending on etching conditions such as a plasma gas concentration at dry etching, or the state of an etching system with high-frequency power or the like and forming a high-accuracy trench.

While the present invention has been described with reference to the illustrative embodiment, this description is not intended to be construed in a limiting sense. Various modifications of the illustrative embodiment will be apparent to those skilled in the art on reference to this description. It is therefore contemplated that the appended claims will cover any such modifications or embodiments as fall within the true scope of the invention.

What is claimed is:

1. A method of manufacturing a semiconductor device, comprising the following steps:
a step for ion-implanting a compound in a semiconductor substrate; and
a step for defining a trench in an area of the ion-implanted semiconductor substrate by etching and detecting an intensity of light emitted from a constituent element of the compound to thereby detect an endpoint of the etching.

2. The method according to claim 1, wherein the endpoint of the etching is detected by quenching an intensity of light emitted from the constituent element.

3. The method according to claim 2, wherein the depth of the trench coincides with a depth for the ion-implantation.

4. The method according to claim 1, wherein the depth of the trench is shallower than the depth for the ion-implantation.

5. The method according to claim 1, wherein the semiconductor substrate is a silicon substrate.

6. The method according to claim 5, wherein the compound is BF₂ and detects an intensity of light emitted from fluorine to thereby detect an endpoint of etching.

7. A method of manufacturing a semiconductor device, comprising the following steps:
a step for ion-implanting BF₂ in a P-type silicon substrate; and
a step for defining a trench in an area of the ion-implanted silicon substrate by etching and detecting an intensity of light emitted from a fluorine element contained in said BF₂ to thereby detect an endpoint of the etching.

8. The method according to claim 7, wherein the depth of the trench is shallower than a depth for the ion-implantation.

9. The method according to claim 8, wherein said ion-implantation of BF₂ is an ion-implanting step for a channel stop.

10. The method according to claim 9, wherein the trench is a device isolation trench.

11. The method according to claim 7, wherein a wavelength of an intensity of emitted light is 660 nm.
